(19) United States
(12) Patent Application Publication
(10) Pub. No.: US 2008/0036097 A1
(43) Pub. Date: Feb. 14, 2008

(54) SEMICONDUCTOR PACKAGE, METHOD OF PRODUCTION THEREOF AND ENCAPSULATION RESIN

(76) Inventors: Teppei Ito, Tokyo (JP); Masahiro Wada, Tokyo (JP); Hiroshi Hirose, Tokyo (JP)

Correspondence Address: SMITH, GAMBRELL & RUSSELL, SUITE 3100, PROMENADE II, 1230 PEACHTREE STREET, N.E., ATLANTA, GA, 30309-3592, US

(21) Appl. No.: 11/835,774

(22) Filed: Aug. 8, 2007

(30) Foreign Application Priority Data
Aug. 10, 2006 (JP) 2006-218117

(51) Int. Cl. H01L 23/29; H01L 21/58; H01L 23/48

(52) U.S. Cl. 257/778; 257/788; 438/127; 257/E21.503; 257/E23.01; 257/E23.121

(57) ABSTRACT

A flip-chip semiconductor package and method of manufacture thereof, the flip-chip semiconductor being highly reliable due to suppression of cracking. The flip-chip semiconductor package is formed by flip-chip bonding of a semiconductor chip-connecting electrode surface of a circuit board 1 and an electrode surface of a semiconductor chip 2, dispensing of an encapsulation resin 4 between the circuit board 1 and the semiconductor chip 2, and formation of fillet 4b by providing the encapsulation resin 4 on peripheral side portions of the semiconductor chip, the fillet 4b having inclined surfaces extending from upper edges 2a of the peripheral side portions of the semiconductor chip 2 outward toward the circuit board, wherein the angle of inclination formed between the inclined surfaces and the peripheral side portions of the semiconductor chip 2 is 50 degrees or less in the vicinity of the upper edges of the peripheral side portions 2a of the semiconductor chip.

### BACKGROUND OF THE INVENTION

(1) Field of the Invention

The technical field of the present invention is generally the field of semiconductor packages and methods for production thereof, more specifically the field of flip-chip semiconductor packages.

(2) Description of the Related Art

In response to the increasing demand in recent years for higher functionality and compactness of electronic devices, their have been rapid advances in the high-density integration and high-density mounting of electronic parts, and the semiconductor packages used for these electronic devices are becoming smaller than ever.

Under these circumstances, in the semiconductor package field, the limits to downscaling of conventional packages using lead frames have recently led to the proposal of area-mounted package formats such as ball-grid arrays (BGA) and chip-scale packages (CSP) in which the chip is mounted on a circuit board. Among such semiconductor packages, the wire bonding format, TAB (tape automated bonding), and the flip-chip (FC) formats are known as formats for connecting semiconductor devices placed on BGA's to substrates, and more recently, many BGA and CSP structures making use of the flip-chip connection format have been proposed as they are more conducive to downscaling of semiconductor packages.

The flip-chip connection format is generally a format in which the input/output terminals of semiconductor chips are formed by forming electrodes known as “bumps” on a semiconductor chip and bringing them into contact with the electrode terminals of the printed-wiring board, then connecting the electrodes of the board using conductive paste or solder. Underfill material (encapsulation resin) consisting of a thermosetting resin can be dispensed between the chip and substrate from the periphery of the semiconductor chip by means of capillary action, then thermally cured in order to raise the strength of the bond between the substrate and the semiconductor chip.

In the above flip-chip semiconductor package, setting and contraction stress of the encapsulation resin and differences in the coefficient of thermal expansion between the semiconductor chip and the substrate may cause stresses to be concentrated at the interface between the semiconductor chip and the underfill material, thus generating cracks and damaging the chip. Therefore, various measures have been conventionally proposed to overcome such problems.

For example, JP H11-67979A (WO 99/09592) proposes a method in which a step of i dispensing encapsulation resin into the gap between the semiconductor chip and the substrate is followed by a step of cutting the semiconductor chip and a fillet until the highest points of the semiconductor chip and the fillet are roughly the same. JP 2000-40775A proposes a method in which the height of a fillet covering the side surface of the semiconductor chip is defined to be within a certain conditional range.

However, conventional solutions still had problems such as not being capable of reliably preventing cracks, and involving complicated procedures.

The present invention was achieved in consideration of the above circumstances, and has the purpose of at least partially resolving the problems of the conventional art. Specifically, it has the purpose of offering a flip-chip semiconductor package and method of manufacture thereof which suppresses and reduces cracking and thereby improves reliability.

### SUMMARY OF THE INVENTION

The present invention offers a flip-chip semiconductor package formed by flip-chip bonding of a semiconductor chip-connecting electrode surface of a circuit board and an electrode surface of a semiconductor chip, dispensing of an encapsulation resin between the circuit board and the semiconductor chip, and formation of fillet by providing the encapsulation resin on peripheral side portions of the semiconductor chip, the fillet having inclined surfaces extending from upper edges of the peripheral side portions of the semiconductor chip outward toward the circuit board, wherein the angle of inclination formed between the inclined surfaces and the peripheral side portions of the semiconductor chip is 50 degrees or less in the vicinity of the upper edges of the peripheral side portions of the semiconductor chip.

Due to this structure, the fillet are provided with a stress-reducing structure of a designated angle of inclination, thereby preventing or reducing cracking that may otherwise occur due to concentration of stresses in the vicinity of the interface between the fillet and the semiconductor chip, thereby achieving high reliability.

Furthermore, the present invention offers a method of producing a flip-chip semiconductor package, comprising a bonding step of flip-chip bonding a semiconductor chip-connecting electrode surface of a circuit board and an electrode surface of a semiconductor chip; and an encapsulation step of dispensing encapsulation resin between the circuit board and the semiconductor chip, and forming fillet by providing the encapsulation resin at peripheral side portions of the semiconductor chip, wherein the encapsulation step is such that the fillet are formed with inclined surfaces extending from upper edges of the peripheral side portions of the semiconductor chip outward toward the circuit board, and the angle of inclination formed between the inclined surfaces and the peripheral side portions of the semiconductor chip is 50 degrees or less in the vicinity of the upper edges of the peripheral side portions of the semiconductor chip.

This method only requires the structure of the fillet to be such as to be inclined by a designated angle of inclination, and thus does not require any troublesome work, while also preventing or reducing cracking that may otherwise occur due to concentration of stresses in the vicinity of the interface between the fillet and the semiconductor chip.

The flip-chip semiconductor package according to the present invention has the effect of preventing or reducing cracking, thus achieving high reliability. Additionally, the method of producing a flip-chip semiconductor package according to the present invention has the effect of enabling a highly reliable flip-chip semiconductor package to be produced without depending on any additional steps that may be troublesome.

### BRIEF DESCRIPTION OF THE DRAWINGS

FIG. 1 is a schematic section view showing an example of a flip-chip semiconductor package of the present invention.

FIG. 2 is a section view showing an example of a flip-chip semiconductor package of the present invention.

FIG. 3 is a photo of the cross section of an example of a conventional flip-chip semiconductor package.

FIG. 4 is a photo of the cross section of an example of a flip-chip semiconductor package of the present invention.

FIG. 5 is a photo of the top surface of an example of a conventional flip-chip semiconductor package.

FIG. 6 is a photo of the top surface of an example of a flip-chip semiconductor package of the present invention.

### DETAILED DESCRIPTION OF THE INVENTION

Herebelow, embodiments of the flip-chip semiconductor package of the present invention and the method for manufacture thereof shall be described in detail with reference to the drawings.

<Regarding the Structure of the Semiconductor Package>

FIG. 1 is a schematic section view showing a flip-chip semiconductor package according to a first embodiment of the present invention. In the drawing, reference number 1 denotes a circuit board and reference number 2 denotes a semiconductor chip with a thickness, for example, of about 100-750 μm, placed on top of the circuit board. The electrode surface for connecting the semiconductor chip on the top surface of the circuit board 1 and the electrode surface on the bottom surface of the semiconductor chip 2 are flip chip bonded by means of a solder ball 3. Additionally, an encapsulation resin 4 is dispensed between the circuit board 1 and the semiconductor chip 2 to form an underfill 4a, and an encapsulation resin 4 is also provided on the peripheral side portions of the semiconductor chip to form fillet 4b.

In this first embodiment, the fillet 4b has a stress-reducing structure, more specifically, a structure reducing the stress from the semiconductor chip 2 acting on the fillet 4b. This structure is such that the surface of the fillet forms an inclined surface extending outward from the top edge of the peripheral side portion 2a of the semiconductor chip 2 toward the circuit board 1, the angle of inclination α between the inclined surface and the peripheral side portions of the semiconductor chip being 50 degrees or less in the vicinity of the upper edges of the peripheral side portions of the semiconductor chip.

Here, throughout the present specification, the angle of inclination α shall be defined as the angle between a first side l and an inclined side n, where the first side l is defined as the line segment with a length of ½T, where T is the height (thickness) of the semiconductor chip, extending along the peripheral side portion of the semiconductor chip from the upper edge of the peripheral side portion of the semiconductor chip (i.e. the side edge portion of the semiconductor chip surface on the side opposite the circuit board on which the semiconductor chip is mounted) toward the circuit board, and the inclined side n is defined as the hypotenuse of a right triangle having sides l and m as the two sides, where the second side m is defined as the line segment perpendicularly intersecting with the first side l and extending from the a r side l to the surface of the fillet. This angle of inclination α is advantageously 30-50 degrees.

By forming the fillet 4b such as to have an inclined portion with a predetermined angle in this way, it is possible to reduce thermal warpage due to differences in the coefficients of thermal expansion between the fillet 4b and the semiconductor chip 2, thus reducing the stress from the semiconductor chip 2 acting on the fillet 4b caused by thermal setting and contraction. As a result, the cracking due to concentration of stress occurring in conventional structures is suppressed or reduced, thereby preventing damage to the semiconductor chip and raising the reliability of flip-chip semiconductor packages. Additionally, by reducing the angle of inclination of the top edge of the fillet, the tensile stress applied to the fillet in the width direction can be redistributed as tensile stress in the height direction, thereby lightening the concentration of stresses in one direction on the constituent elements.

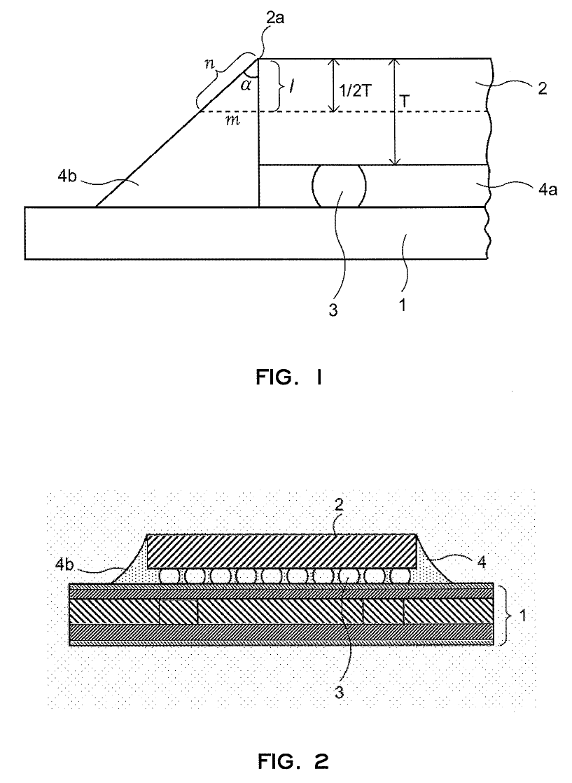

Here, the surface of inclination of the above fillet 4b may be such that the angle of inclination α defined above is 50 degrees or less, and more advantageously, 30-50 degrees. The inclined surface need not be precisely straight, and can be curved outwardly or inwardly, and may in some cases be stepped. FIG. 2 shows an example of the shape of the fillet 4b, in which it is provided with a concave curvature when viewed in a side cross section. Such a fillet shape is easy to produce, enables the volume of the fillet 4b to be reduced, and is capable of redistributing the concentration of stress on the inclined side of the fillet, in particular, further reducing the stress from the semiconductor chip 2 in the width direction acting on the fillet 4b, and thus offering an optimal stress-reducing structure.

### <Regarding the Composition of the Encapsulation Resin>

In FIG. 1, a resin satisfying one, preferably two, and most preferably all of the following properties is used as the encapsulation resin 4:

(1) the resin, when cured, having a glass transition temperature of 60-130° C., more preferably 70-115° C.;
(2) the resin, when cured, having a coefficient of thermal expansion of 15-35 ppm/° C., more preferably 20-35 ppm/° C.; and
(3) the resin, when cured, having a flexural modulus of 5-15 Ga/Pa (25° C.).

By using an encapsulation resin 4 having such properties, the stress from/by the difference with the coefficients of thermal expansion of the circuit board 1 and the semiconductor chip 2 can be reduced, thus enabling the generation of cracks due to concentration of stress to be suppressed or reduced in addition to the effects of the stress reduction structure of the fillet 4b described above.

Since the rate of thermal shrinkage of the encapsulation resin 4 is greater than the rate of thermal contraction of the circuit board 1 and the semiconductor chip 2, the respective components become reciprocally warped due to changes in ambient temperature and the like. Stress is particularly concentrated at the fillet and portion 2a of the semiconductor chip which are in the vicinity of the interface between components, thus making them susceptible to cracking. Therefore, by using encapsulation resins 4 with glass transition temperature satisfying the above condition and low thermal expansion satisfying the above condition, it is possible to relieve the thermal stress caused by differences in the coefficient of thermal expansion or the like between the encapsulation resin 4 and the circuit board 1 or semiconductor chip 2.

Additionally, in FIG. 1, the encapsulation resin 4 is a resin containing at least one type of epoxy resin, and one containing a hardener, a silane coupling agent and an inorganic filler can be used. Such encapsulation resins preferably excel in heat resistance and dielectric properties contributing to improved reliability, and lower the glass transition temperature and reduce flexural modulus of the cured resin by adjusting the crosslinking density, thus contributing to a stress reduction structure as described above.

In FIG. 1, the encapsulation resin 4 may be such that the encapsulation resin used to form the underfill 4a and the encapsulation resin used to form the fillet 4b are the same, or the encapsulation resins may have mutually different properties such as viscosity and coefficient of thermal expansion. Using the same encapsulation resin has the advantage of not having to consider the effects of stress caused by differences in the coefficient of thermal expansion between the encapsulation resins and simplification of work. On the other hand, using different encapsulation resins, for example, enables resins with excellent flowability or the like to be used in the underfill 4a to improve the fill and adhesion of the underfill, and resins having appropriate viscosity to be used in the fillet 4b to improve the filletability and the closeness of contact.

Here, further explaining the encapsulation resin, the above encapsulation resin 4 is a thermosetting resin composition, an embodiment of which may be a liquid epoxy resin composition which has been set, containing (A) an epoxy resin, (B) a hardener, (C) a silane coupling agent and (D) an inorganic filler. Additionally, the above encapsulation resin may contain, in addition to the above components (A)-(D), (E) other additives as needed. Each of the components shall be described below.

The molecular weight and structure of the (A) epoxy resin used in the encapsulation resin 4 are not limited as long as it has at least two epoxy groups in the molecule. Examples include novolac-type epoxy resins, bisphenol-type epoxy resins, aromatic glycidyl amine-type epoxy resins, hydroquinone-type epoxy resins, biphenyl-type epoxy resins, stilbene-type epoxy resins, triphenol methane-type epoxy resins, triphenol propane-type epoxy resins, alkyl substituted triphenol methane-type epoxy resins, triazine nucleus-containing epoxy resins, dicyclopentadiene-modified phenol-type epoxy resins, naphthol-type epoxy resins, naphthalene-type epoxy resins, phenol aralkyl-type epoxy resins, naphthol aralkyl-type epoxy resins and aliphatic epoxy resins.

In this case, resins having a glycidyl ether group or glycidyl amine group bound to an aromatic ring are preferable in view of heat resistance, mechanical properties and moisture resistance. Additionally, the amounts of aliphatic or alicyclic epoxy resins used are preferably limited in view of the reliability, especially the adhesiveness. These may be used alone or as a mixture of two or more types. As an embodiment of the liquid encapsulation resin composition for use in the underfill according to the present invention, the epoxy resin should preferably be ultimately liquid at standard temperature (25° C.), but an epoxy resin which is solid at standard temperature could be used after dissolving it in an epoxy resin which is liquid at standard temperature, resulting in a liquid state.

The molecular weight and structure of the (B) hardener used in the encapsulation resin 4 are not particularly limited as long as it has at least two functional groups in the molecule capable of forming covalent bonds with the epoxy groups in the epoxy resin, with the proviso that if the functional groups are acid anhydride groups, then it has at least one acid anhydride group. Specific examples of functional groups include phenolic hydroxyl groups, acid anhydrides, primary amines and secondary amines.

The above hardeners may be used alone or as a mixture of two or more hardeners containing the same functional groups, and furthermore may be a mixture of two or more hardeners containing different functional groups if within such a range as not to detract from the pot life and the epoxy resin curing ability. When considering the intended use of encapsulation semiconductor devices, phenol resin and aromatic polyamine-type hardeners are preferable in view of heat resistance, mechanical and electronic properties. Furthermore, aromatic polyamine-type hardeners are preferable for having both adhesiveness and moisture resistance.

The amount of hardeners added should be within the range of 0.6-1.4, more preferably 0.7-1.3 by active hydrogen equivalent weight in the hardener with respect to the weight of epoxy in the epoxy resin. Here, the equivalent weight of active hydrogen in the hardener should preferably not be outside the above range, since the reactivity and heat resistance of the composition can be largely reduced. However, if the functional groups contained in the hardener are acid anhydride groups, two carboxylic acid functional groups are derived from a single acid anhydride functional group, so two active hydrogens should be counted for each acid anhydride functional group.

The molecular weight and structure of the (C) silane coupling agent used in the encapsulation resin 4 are not particularly limited as long as they have a chemical structure including a silicon atom bound to an alkoxy group and a hydrocarbon moiety bound to a functional group in the molecule. Examples include epoxysilane coupling agent such as 3-glycidoxypropyltrimethoxyxilane, 3-glycidoxypropyltriethoxysilane, 3-glycidoxypropylmethyldimethoxysilane, 3-glycidoxypropylethyldiethoxysilane and 2-(3,4-epoxycyclohexyl)ethyltrimethoxysilane, silane c coupling agents bound to acrylate groups such as 3-methacryloxypropyltrimethoxysilane, 3-methacryloxypropyltriethoxysilane, 3-methacryloxypropylmethyldimethoxysilane, 3-methacryloxypropylethyldiethoxysilane and 3-acryloxypropyltrimethoxysilane, aminosilane coupling agents such as N-aminoethylated aminopropylmethyldialkoxysilane, N-aminoethylated aminopropyltrialkoxysilane, 3-aminopropyltrimethoxysilane, 3-aminopropyltriethoxysilane, N-phenyl-γ-aminopropyltrimethoxysilane, N-phenyl-γ-aminopropyltriethoxysilane, N-phenyl-γ-aminobutyltrimethoxysilane and N-phenyl-γ-aminobutyltriethoxysilane, latent aminosilane coupling agents wherein a primary amino group of an aminosilane coupling agent is protected by reacting with a ketone or aldehyde such as N-(1,3-dimethylbutylidene)-3-(triethoxysilyl)propyl amine and N-(benzylidene)-3-(triethoxysilyl)propyl amine, mercaptosilane coupling agents such as 3-mercaptopropyltrimethoxysilane, 3-mercaptopropylmethyldimethoxysilane, and silane coupling agents providing functions similar to mercaptosilane coupling agents by pyrolysis such as bis(3-triethoxysilylpropyl)tetrasulfide and bis(3-triethoxysilylpropyl)disulfide. Additionally, these silane coupling agents may be added in pre-hydrolyzed form. They may be used alone or as a mixture of two or more types. In the case of the present invention, epoxy silane coupling agents are preferable in view of the relatively good adhesion to the surfaces of the circuit board and semiconductor devices (solder resist on the surfaces of circuit boards, polyimide on the surfaces of silicon chips and the side surfaces of silicon chips). Aminosilane coupling agents, latent aminosilane coupling agents and mercaptosilane coupling agents are preferable for having very good adhesiveness to the polyimide on the surfaces of silicon chips and silicon nitride surfaces.

Methods of preparing the silane coupling agents include an integral blend process in which the coupling agents are added, dispersed and mixed simultaneously with the mixing of silica filler with other materials in the process of producing the resin composition, a master batch process in which the coupling agent is dispersed and dissolved into (A) the epoxy resin, (B) the aromatic amine hardener and/or the other additives aside from the silica filler, then added to the remaining materials, and a process in which the a silica filler surface layer is chemically modified with a coupling agent, or a combination of these processes. More preferably, a uniform resin composition can be obtained by the master batch process or a method combining the master batch process with the process of chemical modification of the silica surface layer.

Examples of (D) the inorganic filler used in the encapsulation resin 4 include silicic acid salts such as talc, baked clay, unbaked clay, mica and glass, oxides such as titanium oxide, alumina, fused silica (fused spherical silica, fused crushed silica), synthetic silica and silica powders of crystalline silica and the like, carbonic acid salts such as calcium carbonate, magnesium carbonate and hydrotalcite, hydroxides such as aluminum hydroxide, magnesium hydroxide and calcium hydroxide, sulfuric acid salts or sulfurous acid salts such as barium sulfate, calcium sulfate and calcium sulfite, boric acid salts such as zinc borate, barium metaborate, aluminum borate, calcium borate and sodium borate, and nitrides such as aluminum nitride, boron nitride and silicon nitride. These inorganic fillers can be used alone or as a mixture. Among these, fused silica, crystalline silica and synthetic silica powders are preferable for being capable of improving the heat resistance, moisture resistance and strength of the resin composition.

While the shape of the inorganic filler is not particularly limited, it should preferably be spherical in view of the filling properties. In this case, the average particle size of the inorganic filler should preferably be 0.1-20 μm, more preferably 0.2-8 μm. If the average particle size exceeds the above-given lower limit value, the filling ability improves due to a reduction in the viscosity of the resin composition, and it preferably does not exceed the above upper limit value because in that case, the resin will not clog when the resin composition fills the space under the semiconductor device.

The encapsulation resin 4 may include (E) other additives aside from the above components, such as low stress additives, diluents, pigments, flame retardants, surfactants, leveling agents and defoaming agents, as needed.

As the process of producing the encapsulation resin, the components and additives are dispersed and kneaded using a device such as a planetary mixer, a three-roll mill, a two-roll hot rolling mill or an automatic mortar, then defoaming in a vacuum. A heating process can be performed at a temperature range, for example, of 50-200° C., at which a reaction between the epoxy resin and the hardener or decomposition reactions of the respective components do not occur at atmospheric pressure or in a reduced pressure atmosphere for the purpose of eliminating volatile portions of the raw materials beforehand or during the production stage. Additionally, aging can be performed during the dispersion/mixing stage or in a final stage within a range of 12-96 hours at a temperature of 5 to 35° C.

<Regarding the Circuit Board>

In FIG. 1, the circuit board 1 is a multilayer circuit board having at least one insulation layer containing a resin composition with a glass transition temperature of 170-250° C. and a coefficient of thermal expansion of 10-45 ppm/° C. when cured, formed on a core layer containing a resin composition with a glass transition temperature of 160-270° C. and a coefficient of thermal expansion of 10-20 ppm/° C. when cured.

While not limited thereto, the structure may include, for example, a core layer and 2-6 insulation layers, wherein the thickness of the core layer is 20-400 μm and the thickness of the insulation layers is 10-60 μm.

A heat resistant coating layer such as a solder resist may be provided on the outer surface of the circuit board for the purpose of protecting the conductors and maintaining the insulation.

Those skilled in the art will be capable of adjusting the properties of the circuit board 1 without performing excessive experimentation. Since the difference in the coefficient of thermal expansion between the circuit board 1 and the encapsulation resin 4 becomes small when a circuit board 1 having such properties is used, cracking due to concentration of stress can be suppressed or reduced, in addition to the effect of the stress-reducing structure of the fillet 4b and the effect of adjustment of the properties of the encapsulation resin 4.

<Regarding the Core Layer>

In the circuit board 1, the core material used in the core layer is not particularly limited as long as it satisfies the above-described conditions for glass transition temperature and coefficient of thermal expansion, and has adequate strength, but thermosetting resins, for example, panel materials (so-called prepregs) formed by impregnating a fiber base material (e.g. a fiberglass sheet) with a resin composition containing a cyanate resin, a phenol resin, an epoxy resin and an inorganic filler, can be favorably used.

A cyanate resin (including a prepolymer of cyanate resin) is preferably used as the above thermosetting resin, since this enables the coefficient of thermal expansion of the prepreg to be made smaller, and provides excellent electrical properties (low dielectric constant, low dielectric loss tangent) and mechanical strength to the prepreg.

The above cyanate resin can be obtained, for example, by reacting a cyanogen halide and a phenol, then prepolymerizing by methods such as heating as needed. Specific examples include novolac-type cyanate resins and bisphenol-type cyanate resins such as bisphenol A-type cyanate resins, bisphenol E-type cyanate resins and tetramethylbisphenol F-type cyanate resins. Among these, novolac-type cyanate resins are preferred. As a result, the heat resistance due to increased crosslinking density can be improved and the flame retardance of the resin composition can be improved. This is because novolac-type cyanate resins form triazine rings after the curing reaction. Furthermore, it is believed that novolac-type resins have a high proportion of benzene rings in the structure and are easily carbonized. Furthermore, even if the thickness of the prepreg is made 0.5 mm or less, circuit boards prepared by curing a prepreg can be provided with excellent rigidity. In particular, they excel in rigidity when heating, and are therefore highly reliable when mounting semiconductor devices.

An example of the above-mentioned novolac-type cyanate resin is, for example, that indicated by the following formula (I):

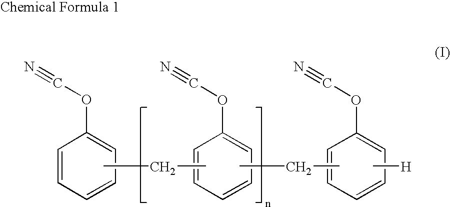

While the average number of repeating units n in the novolac-type cyanate resin indicated by the above formula (I) is not particularly limited, it is preferably 1-10, and more preferably 2-7. If the average number of repeating units n is less than the above lower limit value, the heat resistance decreases and low-molecular-weight compound can come free and vaporize when heated. Additionally, if the average number of repeating units n exceeds the above upper limit value, the melt viscosity can become too high, thus reducing the moldability of the prepreg.

While the weight-average molecular weight of the above cyanate resin is not particularly limited, it should preferably be 500-4,500, and more preferably 600-3,000. If the weight-average molecular weight is less than the above lower limit value, tackiness may occur during preparation of the prepreg, so that prepregs can stick together when coming into contact, or some of the resin can be transferred. Additionally, if the weight-average molecular weight exceeds the above upper limit value, the reaction can proceed too quickly, or molding defects can occur when forming a circuit board, thus reducing the interlayer peeling strength.

The weight-average molecular weight of the above cyanate resin can be measured, for example, by GPC (gel permeation chromatography, standard substance: polystyrene conversion).

Additionally, while not particularly limited, the above cyanate resin can be a single type used alone, a combination of two or more types having different weight-average molecular weights, or a combination of one or more types with their prepolymers.

While the content of the thermosetting resin is not particularly limited, it should preferably be 5-50 wt %, more preferably 20-40 wt % with respect to the entire resin composition. If the content is less than the above lower limit value, it can be difficult to form the prepreg, and if the above upper limit value is exceeded, the strength of the prepreg can decrease.

Additionally, the above resin composition should preferably contain an inorganic filler. As a result, the circuit board can be strengthened even if made thin (thickness 0.5 mm or less). Furthermore, the coefficient of thermal expansion of the circuit board can be further lowered.

Examples of the above inorganic filler include silicic acid salts such as talc, baked clay, unbaked clay, mica and glass, oxides such as titanium oxide, alumina, silica, and fused silica, carbonic acid salts such as calcium carbonate, magnesium carbonate and hydrotalcite, hydroxides such as aluminum hydroxide, magnesium hydroxide and calcium hydroxide, sulfuric acid salts or sulfurous acid salts such as barium sulfate, calcium sulfate and calcium sulfite, boric acid salts such as zinc borate, barium metaborate, aluminum borate, calcium borate and sodium borate, nitrides such as aluminum nitride, boron nitride, silicon nitride and carbon nitride, and titanic acid salts such as strontium titanate and barium titanate. These inorganic fillers can be used alone or as a combination of two or more types. Among these, silica is preferable, and fused silica (particularly spherical fused silica) is preferable for having a low coefficient of thermal expansion. As for their shapes, they may be crushed or spherical, but those suited to the purpose should be used, such as using spherical silica in order to reduce the melt viscosity of the resin composition to ensure good impregnation to the fiber base material.

When using a cyanate resin (particularly a novolac-type cyanate resin) as the above thermosetting resin, it is preferable to use an epoxy resin (substantially containing no halogen atoms).

Examples of the above epoxy resin include, for example, bisphenol-type epoxy resins such as bisphenol A-type epoxy resin, bisphenol F-type epoxy resin, bisphenol E-type epoxy resin, bisphenol S-type epoxy resin, bisphenol M-type epoxy resin, bisphenol P-type epoxy resin and bisphenol Z-type epoxy resin, novolac-type epoxy resins such as phenol novolac-type epoxy resin and cresol novolac-type epoxy resin, arylalkylene-type epoxy resins such as biphenyl-type epoxy resins, xylylene-type epoxy resins and biphenylaralykyl-type epoxy resins, naphthalene-type epoxy resins, anthracene-type epoxy resins, phenoxy-type epoxy resins, dicyclopentadiene-type epoxy resins, norbornene-type epoxy resins, adamantane-type epoxy resins and fluorene-type epoxy resins.

While not particularly limited, the epoxy resin can be a single type used alone, a combination of two or more types having different weight-average molecular weights, or a combination of one or more types with their prepolymers.

Among these epoxy resins, arylalkylene-type epoxy resins are particularly preferable. As a result, it is possible to improve the reflow resistance and flame retardance.

The above-mentioned arylalkylene-type epoxy resin is an epoxy resin having at least one arylalkylene group in the repeating unit. Examples include xylylene-type epoxy resins and biphenyldimethylene-type epoxy resins. Among these, biphenyldimethylene-type epoxy resins are preferred. Biphenyldimethylene-type epoxy resins can be expressed, for example, by the following formula (II).

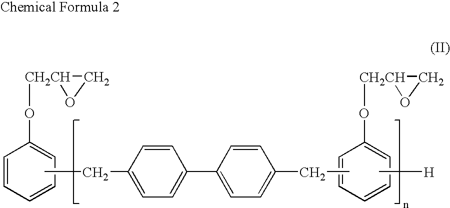

While the average number of repeating units n in the biphenyldimethylene-type epoxy resin expressed by the above formula (II) is not particularly limited, it should preferably be 1-10, more preferably 2-5. If the average number of repeating units n is less than the above lower limit, the biphenyldimethylene-type epoxy resin easily crystallizes and the solubility in general-purpose solvents is relatively low, making it difficult to handle. Additionally, if the average number of repeating units n exceeds the above upper limit, the flowability of the resin decreases, thus causing molding defects and the like.

While the content of the above epoxy resin is not particularly limited, it should preferably by 1-55 wt %, preferably 2-40 wt % with respect to the entire resin composition. If the content is less than the above lower limit, the reactivity of the cyanate resin can become low and the moisture resistance of the resulting product can become poor, and if the upper limit is exceeded, the heat resistance may decline.

While the weight-average molecular weight of the above epoxy resin is not particularly limited, it should preferably be 500-20,000, more preferably 800-15,000. If the weight-average molecular weight is less than the above lower limit, the prepreg can become tacky, and if the upper limit is exceeded, the degree of impregnation to the fiber base material during preparation of the prepreg can be reduced, so as not to be able to obtain a uniform product.

The weight-average molecular weight of the above epoxy resin can, for example, be measured by GPC.

When using a cyanate resin (particularly a novolac-type cyanate resin) as the above thermosetting resin, a phenol resin should preferably be used. Examples of the above-mentioned phenol resin include novolac-type phenol resins, resol-type phenol resins and arylalkylene-type phenol resins. The phenol resin can be a single type used alone, a combination of two or more types having different weight-average molecular weights, or a combination of one or more types with their prepolymers. Among these, arylalkylene-type phenol resins are particularly preferred. As a result, the hygroscopic solder heat resistance can be improved.

Examples of the above arylalkylene-type phenol resin include, for example, xylylene-type phenol resins and biphenyldimethylene-type phenol resins. Biphenyldimethylene-type phenol resins can be expressed, for example, by the following formula (III).

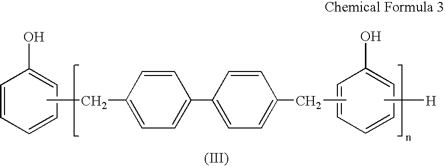

While the average number of repeating units n in the biphenyldimethylene-type phenol resin expressed by the above formula (III) is not particularly limited, it should preferably be 1-12, more preferably 2-8. If the average number of repeating units n is less than the above lower limit, the heat resistance can decrease. Additionally, if the average number of repeating units n exceeds the above upper limit, the compatibility with other resins decreases, thus making it difficult to work with.

The crosslinking density can be controlled and the reactivity can be easily adjusted by combining the aforementioned cyanate resin (particularly the novolac-type cyanate resin) with an arylalkylene-type phenol resin.

While the content of the above phenol resin is not particularly limited, it should preferably by 1-55 wt % with respect to the entire resin composition, more preferably 5-40 wt %. If the content is less than the above lower limit, then the heat resistance may decline, and if the above upper limit is exceeded, then the low coefficient of thermal expansion may be adversely affected.

While the weight-average molecular weight of the above phenol resin is not particularly limited, it should preferably be 400-18,000, more preferably 500-15,000. If the weight-average molecular weight is less than the above lower limit, the prepreg can become tacky, and if the upper limit is exceeded, the degree of impregnation to the fiber base material during preparation of the prepreg can be reduced, so as not to be able to obtain a uniform product.

The weight-average molecular weight of the above phenol resin can, for example, be measured by GPC.

Furthermore, particularly excellent dimensional stability can be achieved by preparing a circuit board using a combination of the above cyanate resin (particularly the novolac-type cyanate resins), the above phenol resin (the arylalkylene-type phenol resins, particularly the biphenyldimethylene-type phenol resins) and the above epoxy resin (the arylalkylene-type epoxy resins, particularly the biphenyldimethylene-type epoxy resins).

While not particularly limited in this manner, the above resin composition should preferably use a coupling agent. The coupling agent raises the wettability of the interface between the thermosetting resin and the inorganic filler, thus enabling the thermosetting resin and inorganic filler to be evenly attached to the fiber base material, and improving the heat resistance, particularly the solder heat resistance after moisture absorption.

While any coupling agent that is normally used may be utilized here, specific examples include one or more coupling agents chosen from among epoxy silane coupling agents, cationic silane coupling agents, amino silane coupling agents, titanate type coupling agents and silicone oil-type coupling agents. As a result, it is possible to raise the wettability of the interface with the inorganic filler, thereby further improving the heat resistance.

While the content of the above coupling agent will depend on the specific surface area of the above inorganic filler, it should preferably be 0.05-3 parts by weight, particularly 0.1-2 parts by weight with respect to 100 parts by weight of the inorganic filler. If the content is less than the above lower limit, then the inorganic filler cannot be adequately covered, thus reducing the effect of improving the heat resistance, and if the upper limit is exceeded, the reaction will be affected, thus reducing the bending strength and the like.

A curing accelerator can be used in the above resin composition if needed. The curing accelerator may be a substance that is publicly known. Examples include organic metal salts such as zinc naphthenate, cobalt naphthenate, tin octylate, cobalt octylate, cobalt (II) bis-acetylacetonate and cobalt (III) tris-acetylacetonate, tertiary amines such as triethylamine, tributylamine and diazabicyclo[2,2,2]octane, imidazoles such as 2-phenyl-4-methylimidazole, 2-ethyl-4-ethylimidazole, 2-phenyl-4-methylimidazole, 2-phenyl-4-methyl-5-hydroxyimidazole and 2-phenyl-4,5-dihydroxyimidazole, phenol compound such as phenol, bisphenol A and nonylphenol, organic acids such as acetic acid, benzoic acid, salicylic acid and paratoluene sulfonic acid, and mixtures thereof. As the curing accelerator, it is possible to use one of the above including derivatives thereof alone, or as a combination of two or more types including derivatives thereof.

While the content of the above curing accelerator is not particularly limited, it should preferably be 0.05-5 wt %, more preferably 0.2-2 wt % with respect to the entire resin composition. If the content is less than the above lower limit, then the curing acceleration effect may not be achieved, and if it exceeds the above upper limit, the storing ability of the prepreg may decline.

The above resin composition may be used in combination with a thermoplastic resin such as a phenoxy resin, a polyimide resin, a polyamideimide resin, a polyphenylene oxide resin, a polyether sulfone resin, a polyester resin, a polyethylene resin or a polystyrene resin, a polystyrene-based thermoplastic elastomer such as a styrene-butadiene copolymer or a styrene-isoprene copolymer, a thermoplastic elastomer such as a polyolefin-based thermoplastic elastomer, a polyamide-based elastomer or a polyester-based elastomer, and a diene-based elastomer such as a polybutadiene, an epoxy-modified polybutadiene, an acryl modified polybutadiene and a methacryl-modified polybutadiene.

Additionally, additives other than the above components may be added to the above resin composition as needed, such as pigments, dyes, defoaming agents, leveling agents, UV absorbing agents, foaming agents, antioxidants, flame retardants and ion catchers/absorbents.

Next, the prepreg shall be explained.

A core material which is a panel material (so-called prepreg) formed by impregnating a fiber base material (e.g. a fiberglass sheet) with a resin composition and curing is suitable for production of circuit boards excelling in various properties such as dielectric properties and reliability of mechanical and electrical connections under high-temperature high-humidity conditions.

Examples of the above fiber base material include glass fiber materials such as glass fabrics and glass non-woven fabrics, synthetic fiber materials composed of fabrics or non-woven fabrics mainly composed of polyamide-based resin fibers such as polyamide resin fibers, aromatic polyamide resin fibers and fully aromatic polyamide resin fibers, polyester-based resin fibers such as polyester resin fibers, aromatic polyester resin fibers and fully aromatic polyester resin fibers, polyimide resin fibers and fluorinated resin fibers, and organic fiber materials such as craft paper, cotton linter paper, and mixed papers of linter and craft pulp. Among these, glass fiber base materials are preferred. As a result, the strength and water absorption rate of the prepreg can be improved. Additionally, the coefficient of thermal expansion of the prepreg can be made small.

Examples of methods for impregnating the fiber base material with a resin composition include, for example, a method of using a resin composition to prepare a resin varnish and immersing the fiber base material in the resin varnish, a method of coating with various types of coaters, and a method of spraying. Of these, the method of immersing the fiber base material in the resin varnish is preferable. As a result, it is possible to improve the degree of impregnation of the fiber base material with the resin composition. When immersing the fiber base material in a resin varnish, conventional impregnation-coating equipment may be used.

While the solvent used in the above resin varnish preferably has good solubility in the resin component of the above resin composition, a poor solvent may be used within such a range as not to have any detrimental effects. Examples of solvents having good solubility include acetone, methylethylketone, methylisobutylketone, cyclohexanone, tetrahydrofuran, dimethylformamide, dimethylacetoamide, dimethylsulfoxide, ethylene glycol, cellosolves and carbitols.

While the solid part of the above resin varnish is not particularly limited, the solid part of the above resin composition should preferably be 40-80 wt %, preferably 50-65 wt %. As a result, the degree of impregnation of the fiber base material with the resin varnish can be further improved. The core material can be obtained by impregnating the above fiber base material with the above resin composition, then drying at a predetermined temperature, for example, 80-200° C.

<Regarding the Insulation Layer>

In circuit board 1, the material used in the insulation layer is not particularly limited as long as it satisfies the above-mentioned conditions on the glass transition temperature and coefficient of thermal expansion of the circuit board 1, and has adequate strength, but it is preferably formed from a resin composition containing a thermosetting resin. As a result, the heat resistance of the insulation layer can be improved.

Examples of the above-mentioned thermosetting resin include phenol resins including novolac-type phenol resins such as phenol novolac resin, cresol novolac resin and bisphenol A novolac resin, and resol-type phenol resins such as unmodified resol phenol resins and oil-modified resol phenol resins such as those modified with tung oil, linseed oil and walnut oil; epoxy resins including bisphenol-type epoxy resins such as bisphenol A epoxy resin, bisphenol F epoxy resin, bisphenol E epoxy resin, bisphenol S epoxy resin, bisphenol Z epoxy resin, bisphenol P epoxy resin and bisphenol M epoxy resin, novolac-type epoxy resins such as phenol novolac-type epoxy resins and cresol novolac-type epoxy resins, biphenyl-type epoxy resins, biphenylaralkyl-type epoxy resins, arylalkylene-type epoxy resins, naphthalene-type epoxy resins, anthracene-type epoxy resins, phenoxy-type epoxy resins, dicyclopentadiene-type epoxy resins, norbornene-type epoxy resins, adamantane-type epoxy resins and fluorene-type epoxy resins; resins having a triazine ring such as urea resins and melamine resins, unsaturated polyester resins, bismaleimide resins, polyurethane resins, diallylphthalate resins, silicone resins, resins having a benzoxadine ring, and cyanate resins.

Of these, one type may be used alone, two or more types having different weight-average molecular weights may be used in combination, or one or more types may be used together with their prepolymers.

Additionally, among these, cyanate resins (including prepolymers of cyanate resins) are particularly preferred. As a result, the coefficient of thermal expansion of the insulation layer can be made small. Furthermore, the electrical properties (low dielectric constant, low dielectric loss tangent) and mechanical strength of the insulation layer are improved.

The above-described cyanate resins can be obtained, for example, by reacting a cyanogen halide with a phenol, and prepolymerizing by methods such as heating as needed. Specific examples include novolac-type cyanate resins and bisphenol-type cyanate resins such as bisphenol A-type cyanate resins, bisphenol E-type cyanate resins and tetramethylbisphenol F-type cyanate resins. Among these, novolac-type cyanate resins are preferred. As a result, the heat resistance due to increased crosslinking density can be improved and the flame retardance of the resin composition can be improved. This is because novolac-type cyanate resins form triazine rings after the curing reaction. Furthermore, it is believed that novolac-type resins have a high proportion of benzene rings in the structure and are easily carbonized.

An example of the above-mentioned novolac-type cyanate resin is, for example, that indicated by the following formula (I):

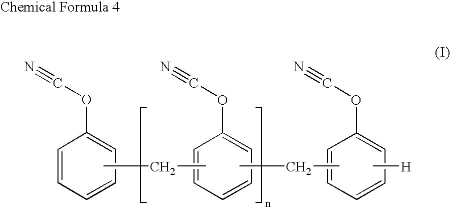

While the average number of repeating units n in the novolac-type cyanate resin indicated by the above formula (I) is not particularly limited, it is preferably 1-10, and more preferably 2-7. If the average number of repeating units n is less than the above lower limit value, the novolac-type cyanate resin easily crystallizes, thus reducing the solubility in general-purpose solvents, making it difficult to handle. Additionally, if the average number of repeating units n exceeds the above upper limit value, the melt viscosity can become too high, thus reducing the moldability of the insulation layer.

While the weight-average molecular weight of the above cyanate resin is not particularly limited, it should preferably be 500-4,500, and more preferably 600-3,000. If the weight-average molecular weight is less than the above lower limit value, the mechanical strength of the insulation layer can be reduced when cured, and furthermore, tackiness may occur upon preparation of the insulation layer, so that some of the resin can be transferred. Additionally, if the weight-average molecular weight exceeds the above upper limit value, the curing reaction can proceed too quickly, or molding defects can occur when forming a base material (particularly a circuit board), thus reducing the interlayer peeling strength.

The weight-average molecular weight of the above cyanate resin can be measured, for example, by GPC (gel permeation chromatography, standard substance: polystyrene conversion).

Additionally, while not particularly limited, the above cyanate resin including its derivatives can be a single type used alone, a combination of two or more types having different weight-average molecular weights, or a combination of one or more types with their prepolymers.

While the content of the thermosetting resin is not particularly limited, it should preferably be 5-50 wt %, more preferably 20-40 wt % with respect to the entire resin composition. If the content is less than the above lower limit value, it can be difficult to form the insulation layer, and if the above upper limit value is exceeded, the strength of the insulation layer can decrease.

When a cyanate resin (particularly a novolac-type cyanate resin) is used as the above thermosetting resin, it should preferably be used together with an epoxy resin (substantially not containing any halogen atoms). Examples of the above epoxy resin include, for example, bisphenol-type epoxy resins such as bisphenol A-type epoxy resin, bisphenol F-type epoxy resin, bisphenol E-type epoxy resin, bisphenol S-type epoxy resin, bisphenol Z-type epoxy resin, bisphenol P-type epoxy resin and bisphenol M-type epoxy resin, novolac-type epoxy resins such as phenol novolac-type epoxy resin and cresol novolac-type epoxy resin, arylalkylene-type epoxy resins such as biphenyl-type epoxy resins, xylylene-type epoxy resins and biphenylaralykyl-type epoxy resins, naphthalene-type epoxy resins, anthracene-type epoxy resins, phenoxy-type epoxy resins, dicyclopentadiene-type epoxy resins, norbornene-type epoxy resins, adamantane-type epoxy resins and fluorene-type epoxy resins.

The epoxy resin can be a single type used alone, a combination of two or more types having different weight-average molecular weights, or a combination of one or more types together with their prepolymers.

Among these epoxy resins, arylalkylene-type epoxy resins are particularly preferable. As a result, it is possible to improve the hygroscopic solder heat resistance and flame retardance.

The above-mentioned arylalkylene-type epoxy resin is an epoxy resin having at least one arylalkylene group in the repeating unit. Examples include xylylene-type epoxy resins and biphenyldimethylene-type epoxy resins. Among these, biphenyldimethylene-type epoxy resins are preferred. Biphenyldimethylene-type epoxy resins can be expressed, for example, by the following formula (II).

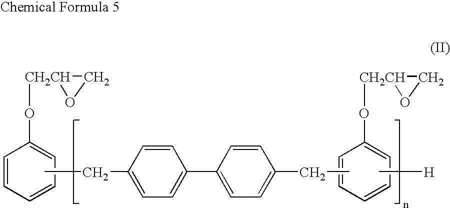

While the average number of repeating units n in the biphenyldimethylene-type epoxy resin expressed by the above formula (II) is not particularly limited, it should preferably be 1-10, more preferably 2-5. If the average number of repeating units n is less than the above lower limit, the biphenyldimethylene-type epoxy resin easily crystallizes and the solubility in general-purpose solvents is relatively low, making it difficult to handle. Additionally, if the average number of repeating units n exceeds the above upper limit, the flowability of the resin decreases, thus causing molding defects and the like. By setting the average number of repeating units n within the above range, it is possible to obtain a resin that excels in the balance between these properties.

While the content of the above epoxy resin is not particularly limited, it should preferably by 1-55 wt %, preferably 5-40 wt % with respect to the entire resin composition. If the content is less than the above lower limit, the reactivity of the cyanate resin can become low and the moisture resistance of the resulting product can become poor, and if the upper limit is exceeded, the low coefficient of thermal expansion and the heat resistance may suffer.

While the weight-average molecular weight of the above epoxy resin is not particularly limited, it should preferably be 500-20,000, more preferably 800-15,000. If the weight-average molecular weight is less than the above lower limit, the insulation layer can become tacky, and if the upper limit is exceeded, the solder heat resistance can be reduced. By setting the weight-average molecular weight within the above range, it is possible to obtain a resin that excels in the balance between these properties.

The weight-average molecular weight of the above epoxy resin can, for example, be measured by GPC.

The above resin composition preferably contains a film-forming resin. As a result, the film-forming ability and handling when producing an insulation layer with a base material can be further improved.

Examples of the above film-forming resin include phenoxy resins, bisphenol F resins and olefin resins.

As the film-forming resin, one of the above types including derivatives thereof may be used alone, two or more types having different weight-average molecular weights may be used in combination, or one or more types may be used together with their prepolymers.

Among these, phenoxy resins are particularly preferred. As a result, it is possible to improve the heat resistance and flame retardance.

While not particularly limited, examples of the above phenoxy resin include phenoxy resins having bisphenol skeletal structures such as phenoxy resins having a bisphenol A skeletal structure, phenoxy resins having a bisphenol F skeletal structure, phenoxy resins having a bisphenol S skeletal structure, phenoxy resins having a bisphenol M skeletal structure, phenoxy resins having a bisphenol P skeletal structure and phenoxy resins having a bisphenol Z skeletal structure; phenoxy resins having a novolac skeletal structure, phenoxy resins having an anthracene skeletal structure, phenoxy resins having a fluorene skeletal structure, phenoxy resins having a dicyclopentadiene skeletal structure, phenoxy resins having a norbornene skeletal structure, phenoxy resins having a naphthalene skeletal structure, phenoxy resins having a biphenol skeletal structure and phenoxy resins having an adamantane skeletal structure.

Additionally, as the phenoxy resin, it is possible to use structures having a plurality of types of these skeletal structures, or to use phenoxy resins wherein the proportions of the respective skeletal structures differ. Furthermore, it is possible to use a plurality of types of phenoxy resins with different skeletal structures, to use a plurality of types of phenoxy resins with different weight-average molecular weights, or to use these in conjunction with their prepolymers.

Among these, it is possible to use phenoxy resins having a biphenyl skeletal structure and a biphenyl S skeletal structure. As a result, the glass transition temperature can be raised by the rigidity of the biphenyl skeletal structure, and the adherence of the plating metal when producing a multi-layered circuit board can be improved by the bisphenol S skeletal structure.

Additionally, it is possible to use phenoxy resins having a bisphenol A skeletal structure and a bisphenol F skeletal structure. As a result, the adherence of the multi-layer circuit board to the inner-layer circuit board at the time of manufacture can be improved. Furthermore, it is possible to use a combination of the above-mentioned phenoxy resin having a biphenyl skeletal structure and a bisphenol S skeletal structure, and a phenoxy resin having a bisphenol A skeletal structure and a bisphenol F skeletal structure.

While the molecular weight of the above film-forming resin is not particularly limited, the weight-average molecular weight should preferably be 1000-100000, and more preferably 10000-60000.

If the weight-average molecular weight of the film-forming resin is less than the above lower limit, then the effect of improving film forming ability is not adequate. On the other hand, if the above upper limit is exceeded, the solubility of the film-forming resin may be reduced. By setting the weight-average molecular weight of the film-forming resin within the above range, it is possible to obtain a resin that excels in the balance between these properties.

While the content of the film-forming resin is not particularly limited, it should preferably be 1-40 wt % with respect to the entire resin composition, more preferably 5-30 wt %.

If the content of the film-forming resin is less than the above lower limit, the effect of improving the film-forming ability is not adequate. On the other hand, if the upper limit is exceeded, the relative content of the cyanate resin is low, thus reducing the effect of providing a low coefficient of thermal expansion. By setting the content of the film-forming resin within the above range, it is possible to obtain a resin that excels in the balance between these properties.

The above-described thermosetting resin and film-forming resin used in the insulation layer should both be such as to contain substantially no halogen atoms. As a result, flame retardance can be achieved without using halogen compounds.

Here, containing substantially no halogen atoms refers, for example, to a halogen atom content in the epoxy resin or phenoxy resin of 0.15 wt % or less (JPCA-ES01-2003).

A curing accelerator may be used in the above resin composition as needed. The curing accelerator may be a publicly known substance. Examples include imidazole compounds, organic metal salts such as zinc naphthenate, cobalt naphthenate, tin octylate, cobalt octylate, cobalt (II) bis-acetylacetonate and cobalt (III) tris-acetylacetonate; tertiary amines such as triethylamine, tributylamine and diazobicyclo[2,2,2]octane; phenol compounds such as phenol, bisphenol A and nonylphenol; organic acids such as acetic acid, benzoic acid, salicylic acid and paratoluene sulfonic acid, or mixtures thereof. As the curing accelerator, it is possible to use one of the above types including derivatives thereof alone, or as a combination of two or more types including derivatives thereof.

Among these curing accelerators, imidazole compounds are most preferable. As a result, it is possible to improve the hygroscopic solder heat resistance. Additionally, while there are no particular limits on the above imidazole compound, they should preferably be compatible with the above cyanate resin, epoxy resin and film-forming resin components.

Here, compatibility with the above cyanate resin, epoxy resin and film-forming resin components refers to the property of dissolving substantially to the molecular level, or dispersing in a state approximate thereto, when the imidazole compound is mixed with the above cyanate resin, epoxy resin and film-forming resin components, or the imidazole compound is mixed with the above cyanate resin, epoxy resin and film-forming resin components together with an organic solvent.

By using such an imidazole compound in the resin composition, the reactions of the cyanate resin or epoxy resin can be effectively accelerated, or similar effects can be achieved even if the content of the imidazole compound is slightly lowered.

Furthermore, resin compositions using these types of imidazole compounds are capable of being cured with a high degree of uniformity from microscopic matrix units between resin components. As a result, the insulating ability and heat resistance of the insulation layer formed on the multi-layer circuit board can be raised.

Additionally, by roughening the surface of an insulation layer formed from such a resin composition, for example, by using an oxidizing agent such as permanganic acid salts or dichromic acid salts, a plurality of microscopic irregularities of high uniformity can be formed on the surface of the insulation layer after the roughening procedure.

By performing a metal plating process on the surface of the insulation layer after the roughening process, the smoothness of the roughened surface can be raised, thus enabling fine conductor circuits to be formed with a high degree of precision. Additionally, the anchor effect can be raised by the microscopic irregularities, thus providing a high degree of adhesion between the insulation layer and the plated metal.

Examples of the above imidazole compound capable of being used in the resin composition of the insulation layer include 1-benzyl-2-methylimidazole, 1-benzyl-2-phenylimidazole, 2-phenyl-4-methylimidazole, 2-ethyl-4-methylimidazole, 2,4-diamino-6-[2′-methylimidazolyl-(1′)]-ethyl-s-triazine, 2,4-diamino-6-(2′-undecylimidazolyl)-ethyl-s-triazine, 2,4-diamino-6-[2′-ethyl-4-methylimidazolyl-(1′)]-ethyl-s-triazine, 2-phenyl-4,5-dihydroxymethylimidazole and 2-phenyl-4-methyl-5-hydroxymethylimidazole.

Among these, imidazole compounds chosen from among 1-benzyl-2-methylimidazole, 1-benzyl-2-phenylimidazole and 2-ethyl-4-methylimidazole are preferable. These imidazole compounds have particular excellent compatibility and therefore enable a high uniformity to be achieved when cured, and are capable of forming a fine and uniform roughened surface, thus enabling fine conductor circuits to be easily formed and providing high heat resistance to the multi-layer circuit board.

While the content of the above imidazole compound is not particularly limited, it should preferably be 0.01-5 wt %, more preferably 0.05-3 wt % with respect to the total amount of the above cyanate resin and epoxy resin. As a result, the heat resistance can be particularly improved.

Additionally, the above resin composition preferably contains an inorganic filler. As a result, it is possible to achieve a low coefficient of thermal expansion and improve the flame retardance. Additionally, the flexural modulus can be improved by combining the above cyanate resin and/or a prepolymer thereof (particularly novolac-type cyanate resin) with an inorganic filler.

Examples of the above inorganic filler include talc, baked clay, unbaked clay, mica, silicic acid salts such as glass, oxides such as titanium oxide, alumina, silica and fused silica, carbonic acid salts such as calcium carbonate, magnesium carbonate and hydrotalcite, hydroxides such as aluminum hydroxide, magnesium hydroxide and calcium hydroxide, sulfuric acid salts or sulfurous acid salts such as barium sulfate, calcium sulfate and calcium sulfite, boric acid salts such as barium metaborate, aluminum borate, calcium borate and sodium borate, nitrides such as aluminum nitride, boron nitride, silicon nitride and carbon nitride, and titanic acid salts such as strontium titanate and barium titanate. As the inorganic filler, it is possible to use one of the above types alone, or a combination of two or more types. Among these, silica is particularly preferred and fused silica (particularly spherical fused silica) is preferred for having a low coefficient of thermal expansion. The shape may be crushed or spherical, but a method of use fit to the purpose should be employed such as by using a spherical silica to reduce the melt viscosity of the resin composition to ensure the impregnation ability to the fiber base material.

While the average particle size of the above inorganic filler is not particularly limited, it should preferably be 0.01-5.0 μm, and more preferably 0.1-2.0 μm.

If the average particle size of the inorganic filler is less than the above lower limit, the viscosity of the resin varnish becomes high when preparing the resin varnish using the resin composition of the present invention, thus affecting the ease of working when preparing an insulation sheet with a base material. On the other hand, if the above upper limit is exceeded, phenomena such as precipitation of the inorganic filler in the resin varnish may occur. By setting the average particle size of the inorganic filler to be within the above range, an excellent balance of these properties can be achieved.

Additionally, while not particularly limited, the above inorganic filler may be an inorganic filler whose average particle size is monodispersed, or an inorganic filler whose average particles size is polydispersed. Furthermore, one or more types of inorganic materials whose average particle sizes are monodispersed and/or polydispersed may be used in combination.

While the content of the above inorganic filler is not particularly limited, it should preferably be 20-70 wt % with respect to the entire resin composition, more preferably 30-60 wt %.

If the content of the inorganic filler is less than the above lower limit, then the effects such as low coefficient of thermal expansion and low water absorption may suffer. Additionally, if the above upper limit is exceeded, the flowability of the resin composition can be reduced, thus reducing the moldability of the insulation layer. By setting the content of the inorganic filler to be within the above range, an excellent balance of these properties can be achieved.

While not particularly so limited, it is preferable for a coupling agent to be used in the above resin composition. The above coupling agent is capable of improving the heat resistance, particularly the hygroscopic solder heat resistance by improving the wettability of the interface between the above thermosetting resin and the above inorganic filler.

While any common coupling agent may be used, it is specifically preferable to use at least one coupling agent chosen from among epoxysilane coupling agents, cationic silane coupling agents, aminosilane coupling agents, titanate coupling agents and silicone oil coupling agents. As a result, the wettability of the interface with the inorganic filler can be raised, thereby improving the heat resistance.

While the content of the above coupling agent is not particularly limited, it should preferably be 0.05-3.00 parts by weight with respect to 100 parts by weight of the inorganic filler.

If the coupling agent content is less than the above lower limit, then the effect of covering the inorganic filler to improve the heat resistance is not adequate. On the other hand, if the above upper limit is exceeded, the bending strength of the insulation layer with base material can be reduced. By setting the content of the coupling agent within the above range, an excellent balance of these properties can be achieved.

The above resin composition may be used in combination with a thermoplastic resin such as a phenoxy resin, a polyimide resin, a polyamideimide resin, a polyphenylene oxide resin, a polyether sulfone resin, a polyester resin, a polyethylene resin or a polystyrene resin, a polystyrene-based thermoplastic elastomer such as a styrene-butadiene copolymer or a styrene-isoprene copolymer, a thermoplastic elastomer such as a polyolefin-based thermoplastic elastomer, a polyamide-based elastomer or a polyester-based elastomer, and a diene-based elastomer such as a polybutadiene, an epoxy-modified polybutadiene, an acryl modified polybutadiene and a methacryl-modified polybutadiene.

Additionally, additives other than the above components may be added to the above resin composition as needed, such as pigments, dyes, defoaming agents, leveling agents, UV absorbing agents, foaming agents, antioxidants, flame retardants and ion catchers/absorbents.

The resin composition used in the insulation layer may be used to impregnate a fiber base material such as fiberglass sheets, or the resin composition may be cured as it is. Here, the method of impregnating the base material with a resin composition is not particularly limited, but an insulation layer with a base material is made by forming a resin layer composed of the above resin composition on a base material.

Here, while the method of forming a resin composition on the base material is not particularly limited, but examples include a method of preparing a resin varnish by dissolving and dispersing the resin composition in a solvent, coating the base material with the resin varnish using various coaters, then drying, or a method of using a sprayer to spray the resin varnish onto the base material, then drying.

Among these, a method of using various types of coaters such as a comma coater or die coater to coat the base material with the resin varnish, then drying is preferable. As a result, it is possible to efficiently produce an insulation layer with base material having no voids and a uniform insulation layer thickness.

While the solvent used in the above resin varnish should preferably exhibit good solubility in the resin components of the above resin composition, a poor solvent may be used within such a range as not to have any detrimental effects. Examples of solvents having good solubility include acetone, methylethylketone, methylisobutylketone, cyclohexanone, tetrahydrofuran, dimethylformamide, dimethylacetoamide, dimethylsulfoxide, ethylene glycol, cellosolves and carbitols.

While the solid content of the above resin varnish is not particularly limited, it should preferably be 30-80 wt % and more preferably 40-70 wt %.

While the thickness of the insulation layer formed from the resin composition in the insulation layer with base material is not particularly limited, it should preferably be 5-100 μm, and more preferably 10-80 μm. As a result, when producing a multi-layer circuit board using this insulation layer with a base material, it is possible to fill the irregularities in the inner layer circuit before molding, and to ensure a suitable thickness for the insulation layer. Additionally, in the insulation layer with base material, it is possible to suppress cracking of the insulation layer and reduce powdering during cutting.

While the base material used in the insulation layer with a base material is not particularly limited, examples include polyester resins such as polyethylene terephthalate and polybutylene terephthalate, thermoplastic resin films having heat resistance such as fluorinated resins and polyimide resins, or metal foils of copper and/or copper alloys, aluminum and/or aluminum alloys, iron and/or iron alloys, silver and/or silver alloys, gold and gold alloys, zinc and zinc alloys, nickel and nickel alloys, and tin and tin alloys.

While the thickness of the above base material is not particularly limited, one of 10-100 μm is preferred for being easy to handle when producing an insulation sheet with base material.

When producing an insulation layer with base material, the irregularities on the surface of the insulating base material on the side attached to the insulation layer should preferably be extremely small. As a result, the functions of the present invention can be effectively achieved.

<Regarding the Method of Producing the Multi-layer Circuit Board>

Next, a multi-layer circuit board using an insulation layer with base material shall be explained.

The above multi-layer circuit board 1 is formed by stacking the above insulation layer with base material to one or both surfaces of an inner layer circuit board, then hot press molding.

Specifically, the insulation layer side of the above insulation layer with base material is placed against the inner layer circuit board, then vacuum hot press molded using a vacuum press laminator or the like, then thermally cured with a hot air dryer or the like.

While the conditions of hot press molding are not particularly limited, an example would be a temperature of 60-160° C. and a pressure of 0.2-3 MPa. Additionally, while the thermal curing conditions are not particularly limited, it can be performed at a temperature of 140-240° C. for 30-120 minutes.

Alternatively, the insulating resin of the above insulation layer with base material can be stacked with an inner layer circuit board, then hot press molded using a plate press. While the conditions for hot press molding are not particularly limited, an example would be at a temperature of 140-240° C. and a pressure of 1-4 MPa.

<Regarding the Method of Producing the Semiconductor Package>

Next, the method of manufacturing the flip-chip semiconductor package in FIG. 1 shall be explained.

An embodiment of the method of the present invention comprises a bonding step of flip-chip bonding a semiconductor chip connecting electrode surface of the circuit board 1 and an electrode surface of the semiconductor chip 2, and an encapsulation step of dispensing a encapsulation resin 4 between the above circuit board 1 and the above semiconductor chip 2 to form an underfill 4a, and providing the encapsulation resin 4 at peripheral side portions of the semiconductor chip 2 to form a fillet 4b.

Since the chip bonding process is no different from conventional processes, its explanation shall be omitted.

While the encapsulation process is no different from conventional processes in terms of the steps in the procedure itself, but during this process, the fillet 4b can be formed with a structure such that the surface forms an inclined plane extending from the upper edge of the peripheral side portion of the semiconductor chip 2 outwardly to the substrate, and the angle of inclination formed by the peripheral side portion of the semiconductor chip 2 and the inclined surface is 50 degrees or less in the vicinity of the upper edge of the peripheral side portion of the semiconductor chip.

More specifically, the above encapsulation step comprises a dispensing step of dispensing encapsulation resin between the circuit board 1 and the semiconductor chip 2 to form an underfill 4a, and a fillet forming step of providing a encapsulation resin at the peripheral side portions of the semiconductor chip to form a fillet 4b. That is, while the underfill 4a and the fillet 4b could be formed by a single dispensing operation, they are formed in two steps, i.e. a dispensing step for forming the underfill 4a and a fillet forming step for forming the fillet 4b, in order to provide the desired structure for the fillet.

The above dispensing step may be such as to coat the side edge portion of the semiconductor ship 2 with an encapsulation resin composition while heating the encapsulation resin composition and the semiconductor package formed by flip-chip bonding of the circuit board 1 and the semiconductor chip 2 before filling with the encapsulation resin so as to enable it to penetrate into the gaps by means of capillary action, and may be used in conjunction with a method of accelerating the dispensing by tilting the semiconductor package or making use of pressure differences for the purpose of shortening the production cycle.

After the above dispensing step is completed, the side edge portion of the semiconductor chip 2 is coated with a encapsulation resin composition to form the fillet 4b. At this time, the fillet 4b should be filled so as not to generate voids.

After filling and coating with the encapsulation resin in this manner, the encapsulation resin is cured by heating for 1-12 hours at a temperature range of 100-170° C. Here, the temperature profile of the curing can be changed, for example, by thermally curing while changing the temperature in steps such as heating at 100° C. for 1 hour, followed by heating at 150° C. for 2 hours.

Here, the encapsulation resin composition forming the underfill 4 and the encapsulation resin composition for forming the fillet 4b in FIG. 1 may be different encapsulation resin compositions with various different properties. However, even when using different encapsulation resin compositions, they should be selected from those having the properties mentioned in the above embodiment of the semiconductor package, but in any case, it is preferable for the viscosity of the encapsulation resin composition for forming the encapsulation resin to be 50 Pa·sec or less (25° C.). Additionally, the circuit board 1 is likewise selected from those having the properties mentioned in the above embodiment of the semiconductor package.

Additionally, the viscosity of the encapsulation resin composition when dispensing the encapsulation resin should preferably be 2 Pa·sec or less. The temperature during dispensing should be 60-140° C., more preferably 100-120° C.

According to the above embodiment, a fillet 4b having a stress-reducing structure can be formed by a conventional method, without the need for additional steps for shaping the fillets to a desired form, such as a cutting step. Additionally, in the above embodiments, the structural design of the fillet can be made easier by using different types of encapsulation resin compositions to form the underfill and the fillet.

In the above embodiment, in addition to the stress-reducing structure of the fillet 4b, the properties of the encapsulation resin 4 and the properties of the circuit board 1 were adjusted to provide stress reduction, but the adjustment of the properties of the encapsulation resin 4 and the properties of the circuit board 1 is optional.

Furthermore, in other embodiments, cracking due to stress concentration is prevented or reduced by adjusting the properties of the encapsulation resin 4 as described above in addition to the stress-reducing structure of the fillet 4b.

Additionally, in other embodiments, cracking due to stress concentration is prevented or reduced by adjusting the properties of the circuit board 1 as described above in addition to the stress-reducing structure of the fillet 4b.

<Regarding the Semiconductor Device>

A semiconductor is fabricated by mounting a flip-chip semiconductor package obtained above onto a printed circuit board. The printed circuit board is not particularly limited as long as it is of a type that is commonly used, such as what is known as a motherboard.

As described above, cracking of the flip-chip semiconductor package due to concentration of stress can be prevented or reduced, thus enabling warpage of the semiconductor package overall to be reduced and improving the connection reliability when mounting on a printed circuit board.

### EXAMPLES

Herebelow, examples of the present invention shall be described, but the present invention is not to be construed as being limited thereto.

### 1. Test of Physical Properties of Cured Resin

Encapsulation resin compositions 1-6 were prepared. Table 1 shows the compositions of the encapsulation resin compositions and the results of measurements of glass transition temperature, coefficient of thermal expansion, flexural modulus and viscosity.

With regard to the glass transition temperature, after the encapsulation resin compositions were cured at 150° C.×120 minutes, they were cut into 5×5×10 mm samples, and these samples were measured using a Seiko TMA/SS120 with a press load of 5 g, in the temperature range of −100° C. to 300° C. at a temperature increase of 10° C./minute. The coefficient of thermal expansion was also obtained by the same measurement. As for the flexural modulus, the encapsulation resin compositions were formed into pieces of width 10 mm, length about 150 mm and thickness 4 mm, cured for 30 minutes in a 200° C. oven, then measured with a tension tester in 3-point bending mode, with a span of 64 mm and a speed of 1 mm/minute, at room temperature (19-26° C.). The flexural modulus was calculated from the initial gradient of the stress-warpage curve thus obtained.

Measurements of viscosity at 25° C. were performed with a Brookfield viscometer equipped with a CP-51 cone at 5 rpm. Measurements of viscosity at 110° C. were performed with a HAAAKE RheoStress RS150 rheometer equipped with a PP-60 cone plate at 1 Hz.

TABLE 1

| | General Name | Product | ER1 | ER2 | ER3 | ER4 | ER5 | ER6 |
|---|---|---|---|---|---|---|---|---|
| Epoxy | Bisphenol F epoxy resin | EXA-LVP | 100 | 75 | 45 | 95 | 75 | 45 |
| Resin | Trifunctional glycidylamine | E-630 | 0 | 25 | 55 | 5 | 25 | 55 |
| Hardener | Aromatic primary amine | Kayahard | 34 | 42 | 51 | 39 | 46 | 51 |
| | hardener | AA | | | | | | |
| Silane | Epoxysilane coupling agent | KBM-403 | 5 | 5 | 5 | 5 | 5 | 5 |
| Coupling | | | | | | | | |
| Agent | | | | | | | | |
| Additive | Stress reducing agent | E-1800-6.5 | 5 | 5 | 5 | 5 | 5 | 5 |
| | Diluent | DGME | 2 | 2 | 2 | 2 | 2 | 2 |
| Filler | Spherical synthetic silica | Admatechs | 220 | 230 | 240 | 320 | 335 | 345 |

| | | | | | | | |
|---|---|---|---|---|---|---|---|
| Properties | Glass transition temperature (° C.) | 70 | 95 | 115 | 85 | 95 | 115 |
| | Coefficient of thermal expansion | 32 | 31 | 33 | 24 | 24 | 22 |
| | (ppm/° C.) | | | | | | |
| | Flexural modulus (GPa: 25° C.) | 9 | 9 | 9 | 10 | 10 | 10 |
| | Viscosity (25° C.) (Pa · sec) | 13.2 | 10.8 | 10.8 | 44.4 | 42 | 44.4 |
| | Viscosity (110° C.) (Pa · sec) | 0.1 | 0.1 | 0.1 | 0.3 | 0.3 | 0.3 |

In the above table:

### ER1-ER6: encapsulation resins 1-6.

### EXA-830LVP: Dainippon Ink and Chemicals, epoxy equivalent 161.

### E-630: Japan Epoxy Resins, N,N-bis(2,3-epoxypropyl)-4-(2,3-epoxypropoxy)anilone, epoxy equivalent 97.5.

### Kayahard AA: Nippon Kayaku, 3,3′-ethyl-4,4′-diaminophenylmethane, amine equivalent 63.5.

### KBM-403: Shin-Etsu Chemical, 3-glycidoxypropyltrimethoxysilane, molecular weight 236.3, theoretical coverage area 330 m²/g.

### Epoxy-modified polybutadiene (1): Nisseki Chemical, E-1800-6.5, number-average molecular weight 1800, epoxy equivalent 250.

Reagent diethylene glycol monoethylether: Wako Pure Chemical Industries.

### 2. Reliability Test: Reflow Resistance Test+Thermal Cycling Test

Furthermore, semiconductor packages were prepared by means of flip-chip mounting using the above encapsulation resins 1-6, circuit boards A-F and silicon chips in the combinations shown in Tables 2-5.

The structures of circuit boards A-F were as follows.

Circuit Board A: Size 50 mm×50 mm, thickness 0.7 mm (690 μm), 8 circuit layers (core substrate: Hitachi Chemical 679FG, thickness 0.4 mm; insulation layer: Ajinomoto ABF-GX13, thickness 40 μm, solder resist layers 25 μm above and below).
Circuit Board B: Size 50 mm×50 mm, thickness 0.5 mm (490 μm), 8 circuit layers (core substrate: Hitachi Chemical 679FG, thickness 0.2 mm; insulation layer: Ajinomoto ABF-GX13, thickness 40 μm, solder resist layers 25 μm above and below).
Circuit Board C: Size 50 mm×50 mm, thickness 0.7 mm (690 μm), 8 circuit layers (core substrate: Sumitomo Bakelite ELC4785GS, thickness 0.4 mm; insulation layer: Sumitomo Bakelite APL3601, thickness 40 μm, solder resist layers 25 μm above and below).
Circuit Board D: Size 50 mm×50 mm, thickness 0.5 mm (490 μm), 8 circuit layers (core substrate: Sumitomo Bakelite ELC4785GS, thickness 0.2 mm; insulation layer: Sumitomo Bakelite APL3601, thickness 40 μm, solder resist layers 25 μm above and below).
Circuit Board E: Size 50 mm×50 mm, thickness 0.5 mm (490 μm), 8 circuit layers (core substrate: Sumitomo Bakelite ELC4785GS, thickness 0.2 mm; insulation layer: Sumitomo Bakelite APL3651, thickness 40 μm, solder resist layers 25 μm above and below).
Circuit Board F: Size 50 mm×50 mm, thickness 0.7 mm (690 μm), 8 circuit layers (core substrate: Hitachi Chemical 679FG, thickness 0.4 mm; insulation layer: Sumitomo Bakelite APL3601, thickness 40 μm, solder resist layers 25 μm above and below).

### (1) Comparative Examples 1-18

### Fillet Size Large Inclination Angle α More than 50°

Conditions: Samples were subjected to a pretreatment at 30° C., 60%, 168 hours, reflow resistance test (peak temperature 260° C., three times)+thermal cycling test (100, 200, 300 cycles at −55° C. (30 minutes)/125° C. (30 minutes)), then inspected for cracks. The number of defective semiconductor packages having cracks with respect to the total number of samples is indicated by “defects/total samples”.

The test results are shown in Tables 2-4.

TABLE 2

| | | | | CE1 | CE2 | CE3 | CE4 | CE5 | CE6 |
|---|---|---|---|---|---|---|---|---|---|
| Circuit | Core Layer | Core Layer | Insulation | Encapsulation Resin Type | | | | | |
| Board | Type | Thickness | Layer Type | ER1 | ER2 | ER3 | ER4 | ER5 | ER6 |
| CB A | 679FG | 0.4 mmt | ABF-GX13 | 0/3 | 3/3 | 3/3 | 0/1 | 1/1 | 1/1 |
| CB B | 679FG | 0.2 mmt | ABF-GX13 | 0/3 | 3/3 | 2/3 | 0/3 | 3/3 | 3/3 |
| CB C | ELC4785GS | 0.4 mmt | APL3601 | 0/2 | 1/3 | 2/2 | 0/1 | 1/1 | 1/1 |
| CB D | ELC4785GS | 0.2 mmt | APL3601 | 0/4 | 2/4 | 2/4 | 0/4 | 2/4 | 2/4 |
| CB E | ELC4785GS | 0.2 mmt | APL3651 | 0/3 | 1/3 | 1/3 | 0/3 | 1/3 | 1/3 |

The semiconductor packages using encapsulation resin 1 and encapsulation resin 4 having low glass transition temperatures particularly excelled in reliability and had a low cracking rate in 100-cycle thermal cycling tests even when the upper edge angle of the fillet was greater than 50°.

TABLE 3

| | | | | CE7 | CE8 | CE9 | CE10 | CE11 | CE12 |
|---|---|---|---|---|---|---|---|---|---|
| Circuit | Core Layer | Core Layer | Insulation | Encapsulation Resin Type | | | | | |
| Board | Type | Thickness | Layer Type | ER1 | ER2 | ER3 | ER4 | ER5 | ER6 |
| CB A | 679FG | 0.4 mmt | ABF-GX13 | 2/3 | 3/3 | 3/3 | 1/1 | 1/1 | 1/1 |
| CB B | 679FG | 0.2 mmt | ABF-GX13 | 2/3 | 3/3 | 2/3 | 2/3 | 3/3 | 3/3 |
| CB C | ELC4785GS | 0.4 mmt | APL3601 | 0/2 | 2/3 | 2/2 | 1/1 | 1/1 | 1/1 |
| CB D | ELC4785GS | 0.2 mmt | APL3601 | 0/4 | 3/4 | 3/4 | 2/4 | 3/4 | 3/4 |
| CB E | ELC4785GS | 0.2 mmt | APL3651 | 0/3 | 1/3 | 2/3 | 0/3 | 1/3 | 2/3 |

The semiconductor packages using encapsulation resin 1 and encapsulation resin 4 having low glass transition temperatures and using circuit boards C and D particularly excelled in reliability and had a low cracking rate in 200-cycle thermal cycling tests even when the upper edge angle of the fillet was greater than 50°. Circuit boards C and D have properties of a low coefficient of thermal expansion and a high glass transition temperature compared to other circuit boards.

TABLE 4

| | | | | CE13 | CE14 | CE15 | CE16 | CE17 | CE18 |
|---|---|---|---|---|---|---|---|---|---|
| Circuit | Core Layer | Core Layer | Insulation | Encapsulation Resin Type | | | | | |
| Board | Type | Thickness | Layer Type | ER1 | ER2 | ER3 | ER4 | ER5 | ER6 |
| CB A | 679FG | 0.4 mmt | ABF-GX13 | 3/3 | 3/3 | 3/3 | 1/1 | 1/1 | 1/1 |
| CB B | 679FG | 0.2 mmt | ABF-GX13 | 2/3 | 3/3 | 2/3 | 2/3 | 3/3 | 3/3 |
| CB C | ELC4785GS | 0.4 mmt | APL3601 | 2/2 | 2/3 | 2/2 | 1/1 | 1/1 | 1/1 |
| CB D | ELC4785GS | 0.2 mmt | APL3601 | 2/4 | 4/4 | 3/4 | 3/4 | 3/4 | 3/4 |
| CB E | ELC4785GS | 0.2 mmt | APL3651 | 1/3 | 2/3 | 3/3 | 1/3 | 2/3 | 2/3 |

None of the semiconductor packages had satisfactory reliability in 300-cycle thermal cycling tests when the upper edge angle of the fillet was greater than 50°, regardless of the properties of the encapsulation resins and the circuit boards.

### (2) Examples 1-6 of Present Invention

### Fillet Size Small Inclination Angle 50° or Less

Conditions: Samples were subjected to a pretreatment at 30° C., 60%, 168 hours, reflow resistance test (peak temperature 260° C., three times)+thermal cycling test (500 cycles at −55° C. (30 minutes)/125° C. (30 minutes)), then inspected for cracks. The number of defective semiconductor packages having cracks with respect to the total number of samples is indicated by “defects/total samples”. The test results are shown in Table 5.

TABLE 5

| | | | | EX1 | EX2 | EX3 | EX4 | EX5 | EX6 |
|---|---|---|---|---|---|---|---|---|---|
| Circuit | Core Layer | Core Layer | Insulation | Encapsulation Resin Type | | | | | |
| Board | Type | Thickness | Layer Type | ER1 | ER2 | ER3 | ER4 | ER5 | ER6 |
| CB A | 679FG | 0.4 mmt | ABF-GX13 | 0/3 | 0/3 | 0/3 | 0/3 | 0/3 | 0/3 |
| CB B | 679FG | 0.2 mmt | ABF-GX13 | 0/2 | 0/2 | 0/2 | 0/2 | 0/2 | 0/2 |
| CB C | ELC4785GS | 0.4 mmt | APL3601 | 0/3 | 0/3 | 0/3 | 0/3 | 0/3 | 0/3 |
| CB D | ELC4785GS | 0.2 mmt | APL3601 | 0/2 | 0/2 | 0/2 | 0/2 | 0/2 | 0/2 |
| CB E | ELC4785GS | 0.2 mmt | APL3651 | 0/3 | 0/3 | 0/3 | 0/3 | 0/3 | 0/3 |
| CB F | 679FG | 0.4 mmt | APL3601 | 0/3 | 0/3 | 0/3 | 0/3 | 0/3 | 0/3 |

### 3. Observation of Shape of Fillet

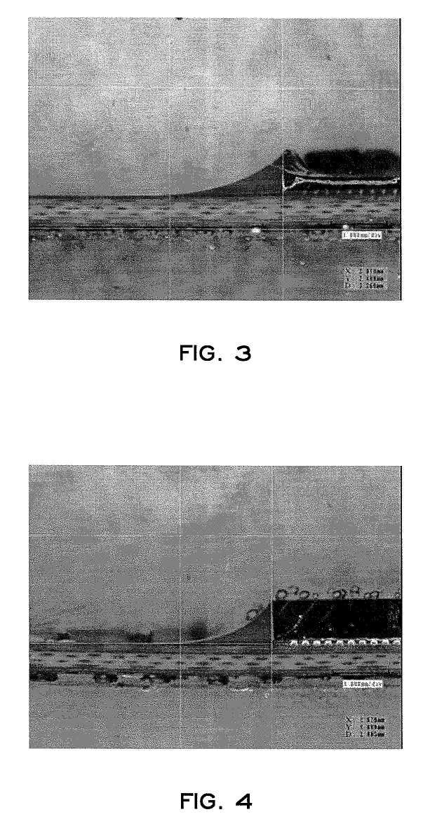

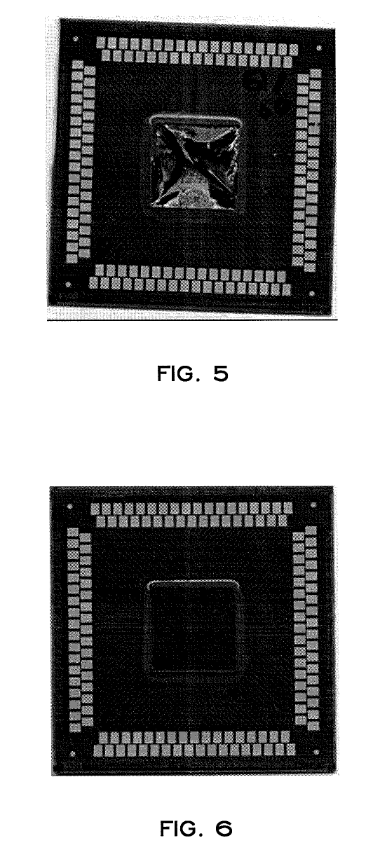

FIG. 3 is a photograph of a cross section of a conventional semiconductor package in which defects occurred in the above reliability tests. Upon measuring the angles in the vicinity of the upper edges of the fillet shown in FIG. 3 by means of the measuring method shown in FIG. 1, the angles of inclination α in Comparative Examples 1-18 were all greater than 50°, that is, either 55°, 53° or 51°. As shown in FIG. 5, the semiconductor chip broke due to cracking.

FIG. 4 is a photograph of a cross section of a semiconductor package of the present invention in which defects did not occur in the above reliability tests. Upon measuring the angles in the vicinity of the upper edges of the fillet shown in FIG. 4 by means of the measuring method shown in FIG. 1, the angles of inclination α in Example 1-6 were found to be respectively 43°, 35°, 35°, 43°, 35° and 35°. Additionally, the side cross sections of the fillet were curved concavely. As shown in FIG. 6, the semiconductor chip was not broken due to cracking.

As a result of the above experiments, it is clear that when the angle in the vicinity of the upper edges of the fillet is 50° or less, the concentration of stresses in the fillet due to contraction of the resins can be suppressed, thus suppressing or reducing cracking, by providing a structure to reduce the stresses applied from the semiconductor chip to the fillet.

Furthermore, a stress-reducing structure between the components can be achieved by optimizing the properties of the encapsulation resin and the circuit board in addition to the above fillet shape, thus enabling a highly reliable flip-chip semiconductor package without cracking to be achieved.

Additionally, solder balls were attached to the BGA surfaces of the semiconductor packages obtained as described above, by printing solder (composition, e.g., Sn-3Ag-0.5Cu), and for example, subjecting to reflow at 250° C. Then, the semiconductor packages were provided on a motherboard substrate (FR-4) having a pad for solder balls for test purposes, and connecting, for example, by reflow at 250° C., to form semiconductor devices. These semiconductor devices were checked to see whether they worked properly, upon which Examples 1-6 were confirmed to have no problems. On the other hand, Comparative Examples 1-18 included some that were satisfactory and some that did not work properly.

1. A flip-chip semiconductor package formed by flip-chip bonding of a semiconductor chip-connecting electrode surface of a circuit board and an electrode surface of a semiconductor chip, dispensing of an encapsulation resin between said circuit board and said semiconductor chip, and formation of fillet by providing the encapsulation resin on peripheral side portions of said semiconductor chip, said fillet having inclined surfaces extending from upper edges of said peripheral side portions of said semiconductor chip outward toward said circuit board, wherein the angle of inclination formed between said inclined surfaces and said peripheral side portions of said semiconductor chip is 50 degrees or less in the vicinity of said upper edges of said peripheral side portions of said semiconductor chip.

2. A flip-chip semiconductor package in accordance with claim 1, wherein said angle of inclination is within the range of 30-50 degrees.

3. A flip-chip semiconductor package in accordance with claim 1, wherein said inclined surface is curved concavely when viewing a side cross section of the fillet.

4. A flip-chip semiconductor package in accordance with claim 1, wherein the glass transition temperature of said encapsulation resin, when cured, is 60-130° C.

5. A flip-chip semiconductor package in accordance with claim 1 wherein the coefficient of thermal expansion of said encapsulation resin, when cured, is 15-35 ppm/° C.

6. A flip-chip semiconductor package in accordance with claim 1, wherein said encapsulation resin is a resin composition containing at least one type of epoxy resin, and further containing a hardener, a silane coupling agent and an inorganic filler.

7. A flip-chip semiconductor package in accordance with claim 1, wherein the viscosity of said encapsulation resin is 50 Pa·sec or less at 25° C.

8. A flip-chip semiconductor package in accordance with claim 1, wherein said circuit board is a multi-layer circuit board comprising a stack of a core layer containing a resin composition with a glass transition temperature of 160-270° C. and a coefficient of thermal expansion of 10-20 ppm/° C. when cured, and at least one insulation layer containing a resin composition with a glass transition temperature of 170-250° C. and a coefficient of thermal expansion of 10-45 ppm/° C. when cured.

9. An encapsulation resin used in a flip-chip semiconductor package as recited in claim 4.

10. A semiconductor device comprising a flip-chip semiconductor package in accordance with claim 1, mounted on a printed wiring board.

11. A method of producing a flip-chip semiconductor package, comprising a bonding step of flip-chip bonding a semiconductor chip-connecting electrode surface of a circuit board and an electrode surface of a semiconductor chip; and an encapsulation step of dispensing encapsulation resin between said circuit board and said semiconductor chip, and forming fillet by providing the encapsulation resin at peripheral side portions of said semiconductor chip, wherein said encapsulation step is such that said fillet are formed with inclined surfaces extending from upper edges of said peripheral side portions of said semiconductor chip outward toward said circuit board, and the angle of inclination formed between said inclined surfaces and said peripheral side portions of said semiconductor chip is 50 degrees or less in the vicinity of said upper edges of said peripheral side portions of said semiconductor chip.

12. A method of producing a flip-chip semiconductor package in accordance with claim 11, wherein the viscosity of said encapsulation resin at the time of dispensing is 2 Pa·sec or less.

13. A method of producing a flip-chip semiconductor package in accordance with claim 11, wherein said encapsulation resin is a resin with a glass transition temperature, when cured, of 60-130° C.

14. A method of producing a flip-chip semiconductor package in accordance with claim 11, wherein said encapsulation resin is a resin with a coefficient of thermal expansion, when cured, of 15-35 ppm/° C.

15. A method of producing a flip-chip semiconductor package in accordance with claim 11, wherein said circuit board is a multi-layer circuit board comprising a stack of a core layer containing a resin composition with a glass transition temperature of 160-270° C. and a coefficient of thermal expansion of 10-20 ppm/° C. when cured, and at least one insulation layer containing a resin composition with a glass transition temperature of 170-250° C. and a coefficient of thermal expansion of 10-45 ppm/° C. when cured.
